(19) United States
(12) Patent Application Publication
(10) Pub. No.: US 2017/0317516 A1
(43) Pub. Date: Nov. 2, 2017

(54) CIRCUIT TO PROVIDE ENERGY PULSES

(71) Applicant: MANTISVISION LTD., Petach Tikva (IL)

(72) Inventor: Eldad STERN, Ra'anana (IL)

(21) Appl. No.: 15/524,270

(22) PCT Filed: Nov. 6, 2014
(86) PCT No.: PCT/US2014/064389

§ 371 Date: May 4, 2017

(51) Int. Cl. H02J 7/00; H01S 5/042; H01S 5/183; G03B 21/20; H02J 7/34

(52) U.S. Cl. CPC H02J 7/0068; H01S 5/183; G03B 21/2033; H01S 5/0428; H02J 7/345

(57) ABSTRACT

A circuit includes an energy storage device configured to provide pulses of energy to a load, a charger circuit coupled to the energy storage device to receive electrical energy from a peak energy constrained supply, a controller coupled to the charger circuit to control the charger circuit to charge the energy storage device as a function of time between pulses to reduce peak energy provided by the peak energy constrained supply.

### RELATED APPLICATION

This application claims priority to U.S. Provisional Application Ser. No. 61/833,501 (entitled “Smart Management Of Power Resources”, filed Nov. 6, 2013) which is incorporated herein by reference.

### BACKGROUND

In mobile systems with a light source which has higher optic power density then ambient light, this light may be used to illuminate the surrounding environment with a pattern of some sort. In order to overcome the ambient light, the light source is operated in pulse mode, so that the density of light emitted during the pulse is higher when compared to the ambient.

Likewise, in other mobile systems such as mobile phones, tablets and laptops that have limited power supply, or have limited output power for external ports such as USB port, supplying high power to loads which operates in pulses may demand large power supply. Also, when using high power Quasi-Continuous Wave (QCW) light sources with a high efficiency driver, output power reflects itself upon the input source.

Another challenge is when the output power varies with time, in which case it has unpredictable current and/or width. Therefore constant current source is not an option. If the momentary output power is reflected onto the power input, it will cause a voltage drop for every output pulse. This can disrupt other units that use the same input power (therefore interfering with Co-existence).

Consumption of large currents in bursts, from an input source that is connected to the driver with wires may cause electrical interference and Electromagnetic Interference (EMI). There are 3 types of power sources currently used in mobile devices: batteries, USB ports & DC power supplies. The stored energy of a battery is dependent on several factors, one of which is the output current. High-current battery discharge reduces the overall capacity of the battery, compared to a low-current discharge. When dealing with a DC power supply the cost and size of the power supply also depends on the peak output power. Lastly, USB ports have limited output power.

There are some known solutions that address these types of problems. Such solutions include: using a capacitor bank in order to reduce the voltage drop, using an inrush current limiter, such as Negative and Positive Temperature Coefficients resistors (NTC, PTC) or inductors, and lastly, using a combination of the above solutions together.

There are a few drawbacks to the existing solutions: The use of a capacitor bank is a space and cost demanding solution. In addition, it does not solve the reflected output current. The inrush current limiter has low efficiency for the NTC solution, and is space 5 demanding for the inductor solution. Furthermore, the limiter does not supply constant current. It only limits the inrush current to a specific value. Lack of dynamic response: that demands specific values (NTC, Inductor) for each duty cycle of the load current (light source).

### SUMMARY

A circuit includes an energy storage device configured to provide pulses of energy to a load, a charger circuit coupled to the energy storage device to receive electrical energy from a peak energy constrained supply, a controller coupled to the charger circuit to control the charger circuit to charge the energy storage device as a function of time between pulses to reduce peak energy provided by the peak energy constrained supply.

### BRIEF DESCRIPTION OF THE DRAWINGS

FIG. 1 is a block diagram of an electric circuit according to an example embodiment.

FIG. 2 is a block diagram of the electric circuit of FIG. 1 including optional sensors in accordance with an example embodiment.

FIG. 3 is a flow-chart illustrating a control loop and a state machine for controlling current in the system of FIG. 1, in accordance with an example embodiment;

FIG. 4 is a flow-chart illustrating a control loop and a state-machine for controlling the current load during each load pulse, in accordance with an example embodiment;

FIG. 5 is a flow-chart illustrating a control loop and a state-machine for controlling the current between load pulses, in accordance with an example embodiment;

FIG. 6 is a flow-chart illustrating a control loop and a state-machine for controlling the current under a variable energy load pulse, in accordance with an example embodiment; and

FIG. 7 is an example of a time diagram illustrating the current consumed in the electronic circuit of FIG. 1 during pulses, in accordance with an example embodiment.

FIG. 8 is a block circuit diagram illustrating dithering of a laser driver according to an example embodiment.

FIG. 9 is a graph illustrating laser driver pulse shaping control for EMI reduction according to an example embodiment.

FIG. 10 is an EMI spectrum analysis of a laser driver with and without dithering according to an example embodiment.

FIG. 11 is a block diagram of electronic circuitry for implementing one or more example embodiments.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software or a combination of software and human implemented procedures in one embodiment. The software may consist of computer executable instructions stored on computer readable media or computer readable storage device such as one or more memory or other type of hardware based storage devices, either local or networked. Further, such functions correspond to modules, which are software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system. The article “a” or “an” means “one or more” unless explicitly limited to a single one.

Unless specifically stated otherwise, as apparent from the following discussions, it is appreciated that throughout the specification discussions utilizing terms such as “processing”, “calculating”, “computing”, “determining”, “generating”, “setting”, “configuring”, “selecting”, “defining”, or the like, include action and/or processes of a computer that manipulate and/or transform data into other data, said data represented as physical quantities, e.g. such as electronic quantities, and/or said data representing the physical objects. The terms “computer”, “processor”, and “controller” should be expansively construed to cover any kind of electronic device with data processing capabilities, or a part thereof.

The term computer should be expansively construed to cover any kind of electronic with data processing capabilities and which is made up of any combination of hardware, software and/or firmware and which includes at least some hardware, even if not labeled as such in the disclosure.

The operations in accordance with the teachings herein may be performed by a computer specially constructed for the desired purposes or by a general purpose computer specially configured for the desired purpose by a computer program stored in a non-transitory computer readable storage medium. The term “non-transitory” is used herein to exclude transitory, propagating signals, but to otherwise include any volatile or non-volatile computer memory technology suitable to the application.

As used herein the term “memory” refers to any readable medium for storing data for the short and/or long term, locally and/or remotely. Examples of memory include inter-alia: any type of storage device including floppy disk, hard disk, optical disk, CD-5 ROMs, magnetic-optical disk, magnetic tape, flash memory, random access memory (RAMs), dynamic random access memory (DRAM), static random access memory (SRAM), read-only memory (ROMs), programmable read only memory PROM, electrically programmable read-only memory (EPROMs), electrically erasable and programmable read only memory (EEPROMs), magnetic card, optical card, any other type of storage device or media suitable for storing electronic instructions and capable of being coupled to a system bus, a combination of any of the above, etc.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) is included in at least one embodiment of the presently disclosed subject matter. Thus the appearance of the phrase “one case”, “some cases”, “other cases” or variants thereof does not necessarily refer to the same embodiment(s).

It is appreciated that, unless specifically stated otherwise, certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination. Any trademark occurring in the text or drawings is the property of its owner and occurs herein merely to explain or illustrate one example of how the presently discussed subject matter may be implemented.

In various embodiments, a system that may include hardware together with a suitable control scheme, provides balancing of input vs. output power by means of a controllable current source. The system may achieve multiple goals including but not limited to low input inrush current by means of semi-constant current or power, low voltage drop over the input voltage and finally, a low-cost, space-saving solution. In addition, the system can reduce electrical interference, Electromagnetic Interference (EMI) and Electromagnetic Conduction (EMC).

The system may be used for providing power to a wide variety of loads in hand held device. For example, the system may be implemented in mobile systems which include a light source which has higher optic power density then ambient light, such as the ones discussed in the background. Furthermore, the system may be used, for example, in mobile systems such as mobile phones, tablets and laptops that have limited power supply, or have limited output power for external ports such as USB port. The system and method may also be used for reducing co-interference to electronic circuits caused by the inrush current of the high-power load (for example a light source) as discussed below in greater detail, the output power may vary with time, in which case it has unpredictable current and/or width. It is noted that the buffering electric circuit disclosed may be used in systems in which the load power consumption is Quasi Continues Wave. It is noted that the buffering electric circuit disclosed may be used in systems in which the load is a repetitive pulse load

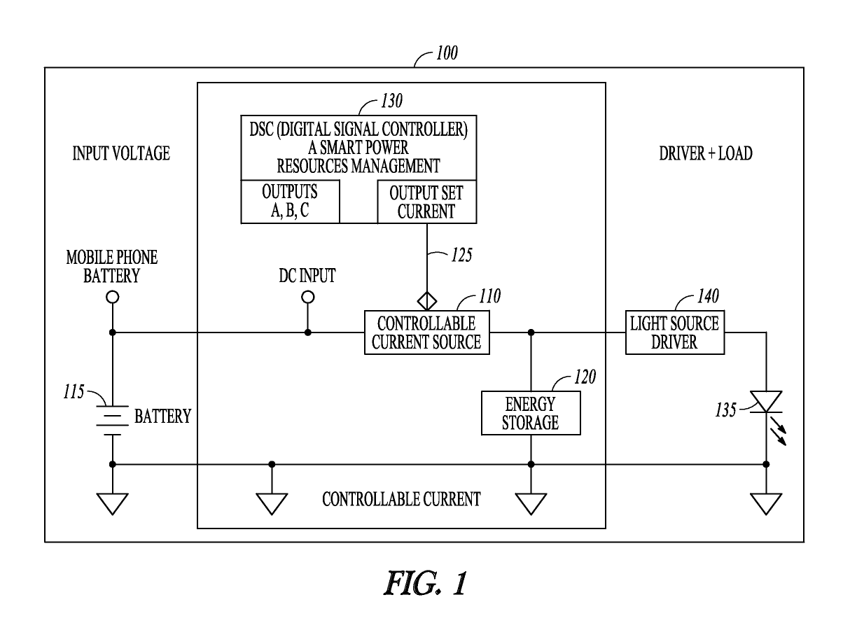

FIG. 1 is a block diagram illustrating an example of a buffering electric circuit 100. The buffering electric circuit includes a controllable current source 110 which is configured to obtain power from a power source 115 and to provide energy to an energy storage module 120. The controllable current source 110 is configured to provide the energy to the energy storage module 120 based on current control commands 125, which are issued by a controller 130 included in the buffering electric circuit 100. The circuit 100 is used to provide energy to a load 135 which operates in pulses provided via a driver 140. Such a load 135 may be, for example, a light source (such as LED, LASER or VCSEL), another example is an RF beacon transmitter in portable hand-held devices. As discussed below in greater detail, the power source 115 from which the controllable current source obtains power is usually a direct current (DC) power source. In some embodiments, the load provides a pulse of light every 5 to 100 msec. The amount of energy to provide the pulse may significantly exceed the capacity of a battery based power supply to provide current and maintain an adequate voltage level. Such pulses may also harm the battery life.

Alternatively to the example shown in FIG. 1, the illustrated electric system may in some examples include fewer, more and/or different modules than shown in FIG. 1. Alternatively to the example shown in FIG. 1, the functionality of the system may in some examples be divided differently among the modules illustrated in FIG. 1. Alternatively to the example shown in FIG. 1, the functionality of the illustrated system described herein may in some examples be divided into fewer, more and/or different modules than shown in FIG. 1 and/or the buffering electric circuit system may in some examples include additional, less, and/or different functionality than described herein.

The buffering electric circuit 100 includes energy storage module or medium 120, which may be implemented in many ways, as will be clear to a person who is of skill in the art. For example, the energy storage medium may include a capacitor, super capacitor, an inductor, or any combination of one or more inductors and capacitors. The energy storage module is connected to the load 135, thereby enabling the source to obtain power from the energy storage medium during its on time.

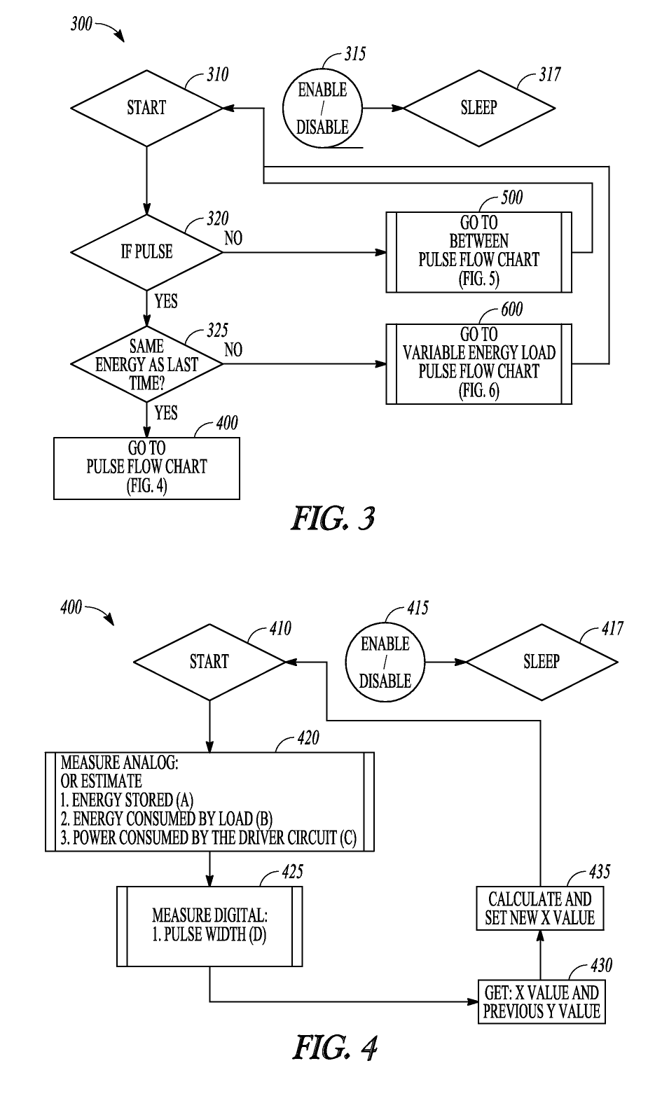

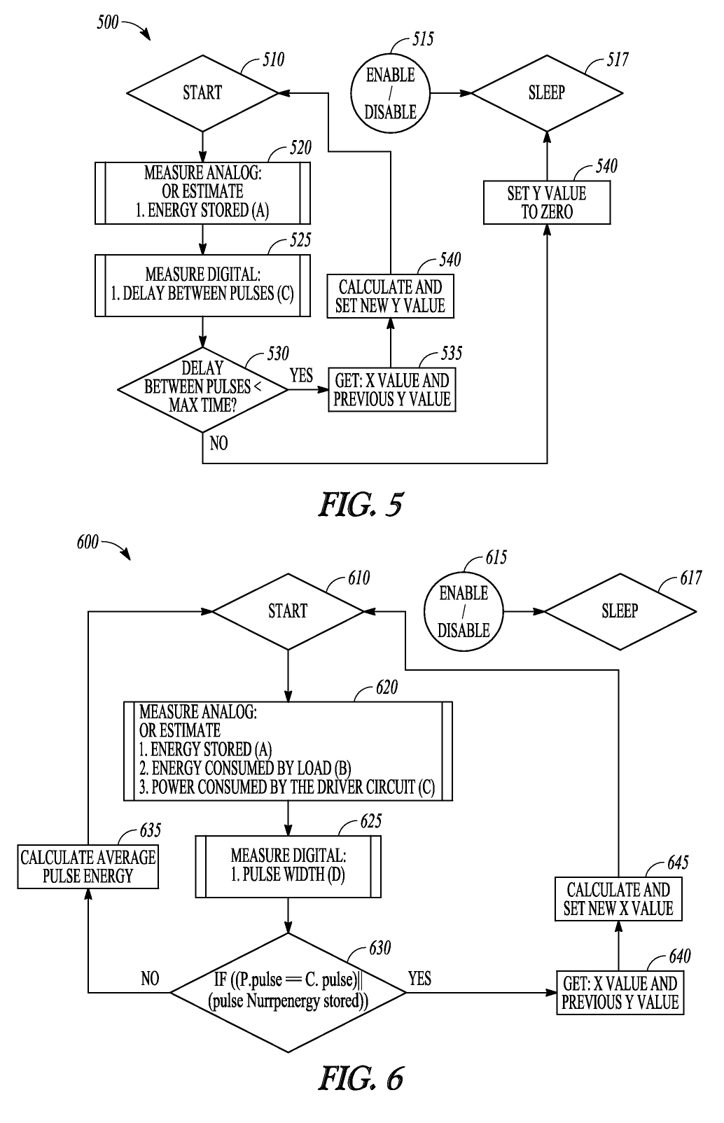

The controller 130 is configured to determine the current commands based on which the controllable current source operates. The controller may be implemented in an analog fashion, in a digital fashion, or in any combination thereof, including a digital signal controller, microprocessor or other controller. While not necessarily so, the controller may be configured to determine the current command by implementing an algorithm such as any one or more of the algorithms discussed with reference to the figures: FIG. 3, FIG. 4, FIG. 5 and FIG. 6.

In one embodiment, the controller may be configured to obtain: (a) information indicative of the amount of energy stored in the energy storage module; (b) information indicative of the amount of energy consumed by the load in the last pulse; and (c) information indicative of the time between the last pulse and a consecutive pulse. In further embodiments, the controller may operate based on a known amount of energy to provide to the energy storage module between pulses. In still further embodiments, the controller may take into account other loads coupled to receive power from the power supply and may time the provision of power to times when the energy storage device is not being charged.

The controller 130 may be configured to compute the current command based on (a), (b), and (c). As can be seen, since the parameters used by the controller may change from time to time, the current control commands 125 issued by the controller may also change during an operation of the buffering electric circuit.

The electric circuit 100 may include or otherwise be associated with one or more controllers 130 configured to execute operation as disclosed herein. The term controller as used herein should be expansively construed to cover any kind of electronic device with data processing capabilities, including, by way of non-limiting example, a personal computer, a server, a computing system, a communication device, a processor (e.g. digital signal processor (DSP), a microcontroller, a field programmable gate array (FPGA), an application specific integrated circuit (ASIC), etc.), any other electronic computing device, and or any combination thereof. In addition, the controller can be implemented by analog circuit or analog control loop.

It is noted that different systems of measurements may be used for implementing various embodiments, and therefore different units of measurements may be used. For example, under the International System of Units (SI), the following units may be used for the above identified parameters (a), (b) and (c): (a) Information indicative of the size of energy stored unit [J]. (b) Information indicative of the Load output energy [J] or power [W]. (c) Information indicative of the time between the pulses [mSec] or [S]

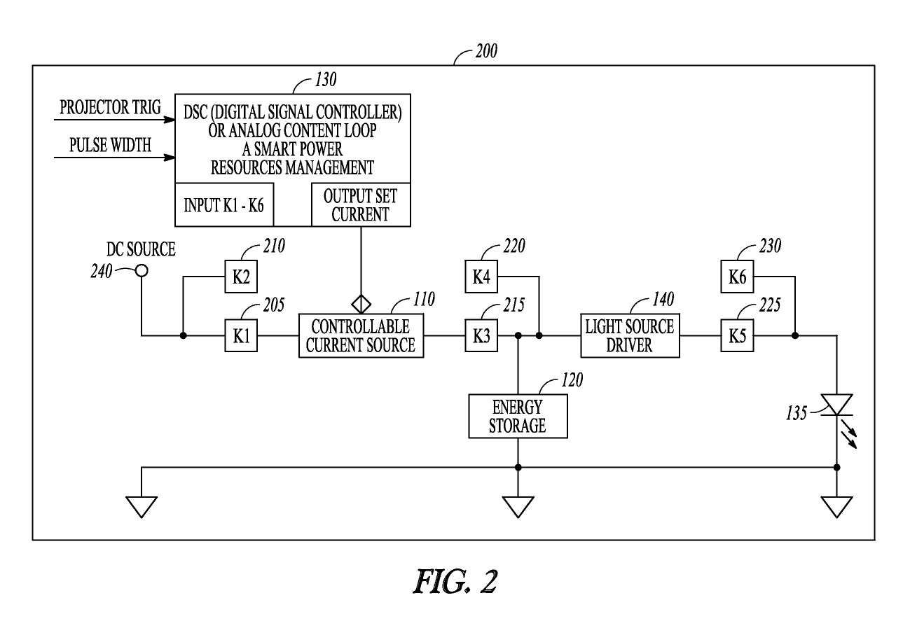

FIG. 2 is a block diagram illustrating an example of a buffering electric circuit 200 on which different types of measurements that can be extracted are illustrated, denoted as 1 205, K2 210, K3 215, K4 220, K5 225, and K6 230, in accordance with the present invention. It is noted that not necessarily all of K1 through K6 are measured in each implementation of the system, nor that each such system necessarily include sensor for measuring all of the parameters K1 through K6. Different combinations may be measured in different implementation, and other sources of information may also be used, as long as parameters (a), (b) and (c) above are available for the controller. A power source 240 may be a battery or other power source in various embodiments.

In one embodiment, the relationship between power in and power out is expressed as:

Eq1 Pin=Pout[W]

In one optimal system 200, efficacy may be added:

Eq2 Pin·η=Pout[W]

Where η=efficacy, Pin=Vin·Iin[W]and

Pout=Vout·Iout[W], in a high efficacy

Driver for example.

Eq3 Vin·Iin·η=Vout·Iout[W] [symbol] 4.2·Iin·0.85=2·10[W]→3.4·Iin=20[W]→Iin=5.9[A]At input 4.2V, load 10 Ampere 2 Volt and efficacy=85%. For light source pulse with duty cycle of 10%

Eq4 Vin·Iin·η=Dcycle·Vout·Iout[W]→4.2·Iin·0.85=0.1·2·10[W]→0.34·Iin=20[W]→Iin=0.59[A]

And for lower duty cycle (DC) less input current may be received. The values of the load, input voltage, efficacy and duty cycle may vary, depending on the desired working conditions.

The parameters for the equations can be extracted from optional sensors by the following equations

Eq5 Vin=Iin[W]; Iin=K1; Vout=K6; Iout=K5;

Energy stored in the energy storage module for two cases: capacitor and inductor:

Eq6 Ecapacitor=0.5·C·V2;Einductor=0.5·L·I2inductor Where C=Estimated; L=Estimated; Iinductor=K3; Vcapacitor=K4; DC=(pulse_width)/(time_between_pulses)

The estimation can be done by a parameter (schematic value) or by inducing current to the energy storage module until it is full and measuring the amount of energy needed for the task. For example, the following stopping conditions may be used: for an energy storage module which is a capacitor: V max, and for an energy storage module which is an inductor: I max.

FIG. 3 illustrates a main control flow chart for a method 300. It incorporates three sub control loops which are illustrated respectively in FIGS. 4, 5 and 6. A main control loop may start at 310 with an “enable” signal at 315. Note that at 315, a disable signal may be alternatively provided to enter a sleep mode at 317. When enabled, method 300 operates under the assumption that the energy storage module is full. If there is a pulse as determined at 320 (energy consumed by the load) and the same energy as used in the last pulse will be used as determined at 325 the controller executes a process 400 illustrated in FIG. 4.

In one optimal system 200, efficacy may be added:

Eq2Pin·η=Pout[W]

Where η=efficacy, Pᵢₙ=Vᵢₙ·Iᵢₙ[W] and Pₒᵤₜ=Vₒᵤₜ·Iₒᵤₜ[W] , in a high efficacy

Driver for example.

Eq3 Vᵢₙ·Iᵢₙ·η=Vₒᵤₜ·Iₒᵤₜ[W] [symbol] 4.2·Iᵢₙ·0.85=2.10[W]3.4·Iᵢₙ=20[W]→Iᵢₙ=5.9[A] At input 4.2V, load 10 Ampere 2 Volt and efficacy=85%. For light source pulse with duty cycle of 10%

Eq4Vᵢₙ·Iᵢₙ·η=D_{cycle}·Vₒᵤₜ·Iₒᵤₜ[W]→4.2·Iᵢₙ·0.85=0.1·2·10[W]→0.34·Iᵢₙ=20[W]→Iᵢₙ=0.59[A]

And for lower duty cycle (DC) less input current may be received. The values of the load, input voltage, efficacy and duty cycle may vary, depending on the desired working conditions.

The parameters for the equations can be extracted from optional sensors by the following equations

Eq5Vin=Iᵢₙ[W]; Iᵢₙ=K1; Vₒᵤₜ=K6; Iₒᵤₜ=K5;

Energy stored in the energy storage module for two cases: capacitor and inductor:

Eq6 Ecapacitor=0.5·C·V2; Einductor=0.5L·I2inductor Where C=Estimated ; L=Estimated; Iinductor=K3; V_{capacitor}=K4; DC=(pulse_width)/(time_between_pulses)

The estimation can be done by a parameter (schematic value) or by inducing current to the energy storage module until it is full and measuring the amount of energy needed for the task. For example, the following stopping conditions may be used: for an energy storage module which is a capacitor: V max, and for an energy storage module which is an inductor: I max.

FIG. 3 illustrates a main control flow chart for a method 300. It incorporates three sub control loops which are illustrated respectively in FIGS. 4, 5 and 6. A main control loop may start at 310 with an “enable” signal at 315. Note that at 315, a disable signal may be alternatively provided to enter a sleep mode at 317. When enabled, method 300 operates under the assumption that the energy storage module is full. If there is a pulse as determined at 320 (energy consumed by the load) and the same energy as used in the last pulse will be used as determined at 325 the controller executes a process 400 illustrated in FIG. 4. If at 320, there is no pulse to be delivered, a method 500 in FIG. 5 is entered to operate between pulses. If at 325, the amount of energy to be used in the pulse is not the same as the previous pulse, a method 600 in FIG. 6 may be entered to determine the energy needed for a variable energy load.

At 400 in FIG. 4 the energy used by the load is calculated by the controller. Starting at 410, if enabled at 415, as opposed to entering sleep mode at 417, several analog values may be measured, estimated, or obtained at 420, including energy stored (a), energy consumed by the load (c) and power consumed by the driver circuit (d). A digital pulse width (b) may be measured at 425. An X value and a previous Y value may be obtained at 430, and a new X value may be calculated and set at 435 for use in charging the energy storage module. At the first pulse predetermined values may be used for X & Y (instead of calculating them, as done in later pulses). Optionally, the predetermined values used for X and Y may be calculated for a soft start (minimal needed current).

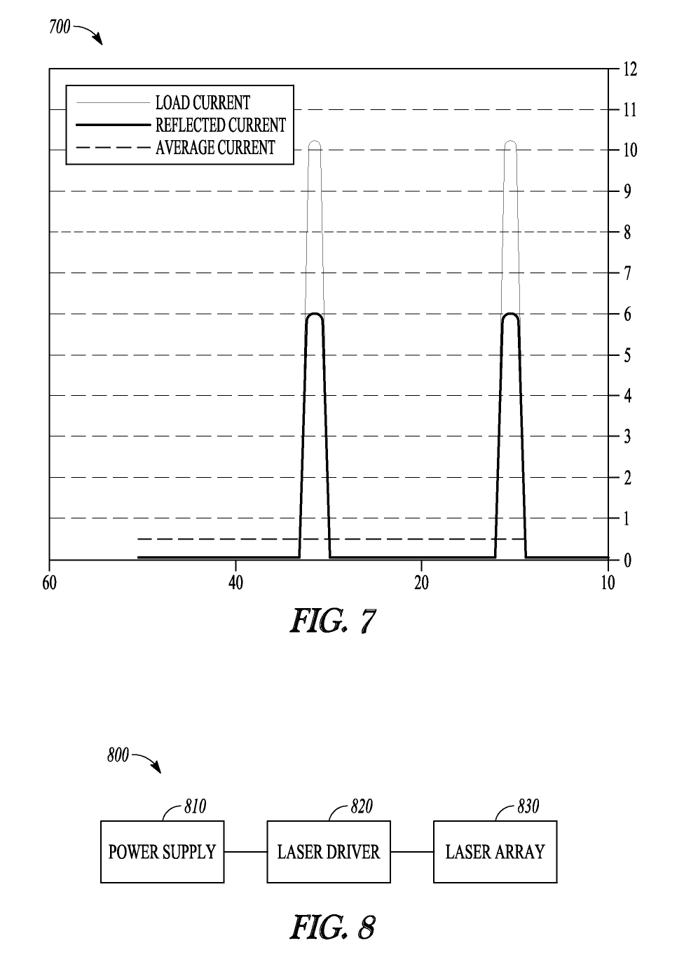

The parameter X represents the set value calculated for the current source during pulse. The parameter Y represents the set value calculated for the current source between pulses. As can be seen in a current flow diagram in FIG. 7 it will be clear to a person who is of skill in the art that equivalent parameters may be used.

In the diagram of FIG. 7: ordinate (y axis) units are Ampere [A], abscissa (x axis) units are Time [mSec]. the load current is set for the example at 10[A] pulse width 2[mSec] duty cycle 10%. The reflected current is the practical, current taken from the input for high efficiency drivers. The average current is the current taken from the input for the propose invention.

The control loop that determines the values for X may be based on a fuzzy and a simple PID (proportional integral derivative) controller. When the pulse ends the state machine goes back to the start 310 and to method 500 in FIG. 5. Method 500 starts at 510 if enabled at 515, else a sleep mode is entered at 517. At 520, an analog measurement or estimate of energy stored in the energy storage module is performed. At 525, a delay between pulses is measured, and a determination is made at 530 whether the delay is less than a maximum time. If yes, at 535, the X value and a previous Y value are obtained, and at 540 a new Y value is calculated and set. If the delay is not less than the maximum time, at 540, the Y value is set to zero and sleep mode 517 is entered.

At method 500 the value Y for between pulses is calculated and the time between the pulses is measured. The measured value may be used in the following equation to calculate the duty cycle for Eq4.

Eq7 DC=(pulse_width)/(time_between_pulses)

If the time exceeds a value (whether a predetermined value or a dynamically calculated one) the controller may execute a sleep command, to reduce power consumption.

Eq8 Valueₛₗₑₑₚ=[(pulse_width·Pulse_power)/(time_between_pulses)≦(minimum current)]→[(pulse_width·Pulse_power)/(minimum current)≦(time_between_pulses)]

Where “minimum current” refers to the current source minimal efficient current, as will be clear to a person who is of skill in the art. One may receive the pulse width and the pulse power from FIG. 4, or one my use a constant value for the Known parameters. FIG. 6 deals with a complex mode of operation 600 in which the pulses have different width and current. If this is the case, starting at 610 when enabled at 615, as opposed to disabled and entering sleep mode 617, the controller may be configured to take a measurement at 620 of at least two pulses and their widths at 625. If at 630, there is no significant difference, at 635 the average energy being consumed by the load is calculated. This value is then used instead of the momentary pulse energy, to calculate the current source set value. If there is a difference, the X value and previous Y values are obtained at 640 and a new X value is calculated at 645.

Utilization of the electric buffering circuit in various systems, various conditions and for various types of loads and powering schemes, may provide any combination of one or more of the following advantages, as well as additional advantages as will be clear to a person who is of skill in the art: High efficiency, less heat dissipation, longer battery life, smaller size (It takes less space: less than 0.1 the size of an NTC inductor solution), operation in variable working condition (due to the algorithm) such as: output power, pulse width and frequency, without adjusting the hardware, can be achieved. When using none static working conditions, the dynamic control can offer special modes of operation that overcomes the sporadic demands for power. Co-existence: if the momentary output power is reflected onto the power input, it will cause a voltage drop for every output pulse. This can disrupt other units that use the same input power. Electromagnetic Interference (EMI): Consumption of large currents 5 in bursts, from an input source that is connected to the driver with wires may cause EMI emissions.

The use of the above described techniques is beneficial for at least the following types of power sources: battery, USB port & DC power supply. By using the proposed technique, the power source (battery, USB port or DC power supply) will supply only the average output power instead of the momentary output power. It can reduce the power source output current by a factor of at least 10 (depend on the output duty cycle).

In many situations, without the proposed solution one won't be able to use USB port as the power supply, for the driver. By reducing the peak output power one can reduce system cost and physical size.

Between the input voltage (battery, USB port or DC supply) and load there is a buffer. This buffer is a controllable current source. The current source is connected to an energy storage module (such as a capacitor), at the input of the light source driver. This capacitor delivers the peak power needed for the driver, Instead of the input source.

In order to determent the current that is required from the input current source several input parameters can be used. Some or all of the following parameters are gathered: (a) the amount of energy stored in the energy storage module; (b) the of amount of energy consumed by the load in the last pulse; (c) the time between the last pulse and a consecutive pulse; (d) the energy consumed by the auxiliary circuit: load (e.g. driver) and buffer (e.g. energy storage module). This information can be calculated or estimated using some or all parameters.

Parameters : K1-Input current (is known by a formula), K2-Input voltage, K3-Output current (is known as being set by the current source), K4-Output voltage, K5-Load current, K6-Input voltage, Projector pulse width.

It is noted that the obtaining of the time between the last pulse and a consecutive pulse may also be implemented by obtaining information on the delay between pulses. The proposed invention may use some or all the parameters, under as specific conditions: some or all the parameters can be used as constants, in the equations. The equations are used to evaluate the output average power. The algorithm is used to establish a smooth transaction between the different working conditions and/or states.

The current source can be implemented in one of the following two ways: Linear—via a power transistor, FET, MOSFET or LDO. Switching power supplies: such as Buck, Boost, Sepic, switching capacitor etcetera.

The control scheme (which may be implemented as an algorithm, as an analog controller, analog feedback circuit etc.) may work in the following manner: All relevant values are gathered—voltage, current and digital sensors inputs. After receiving all relevant information, a two type of control loops are applied to the data. Depending on the position on the process flow chart (FIG. 4) the corresponding value is sent to the current source.

As aforementioned, the electric buffering circuit may be used in many systems. For example, hand-held apparatus configured to obtain distance data from a 2D image of a scene (e.g. implemented in a Smartphone) may include the disclosed buffering electric circuit.

For example, any of the apparatuses disclosed in U.S. patent application Ser. No. 11/837,553 entitled “3D GEOMETRIC MODELING AND MOTION CAPTURE USING BOTH SINGLE AND DUAL IMAGING” (which is incorporated herein in its entirety by reference) may utilize the disclosed electric circuit in the following way: An apparatus configured to obtain distance data from a 2D (two-dimensional) image of a scene including one or more objects, said apparatus including: (a) a bi-dimensional coded light pattern including multiple appearances of a finite set of feature types, each feature type being distinguishable according to a unique bi-dimensional formation; (b) a projector configured to project the coded light pattern on the objects, such that a distance between adjacent epipolar lines associated with substantially identical appearances of any given feature type is minimized according to a limiting epipolar separation factor, giving rise to a plurality of distinguishable epipolar lines separated by approximately a minimum safe distance for epipolar line distinction; and (c) the buffering electric circuit discussed with respect to FIG. 1, wherein the buffering electric circuit is electrically connected to the projector for providing power to the projector; wherein the projector enables an imaging unit to capture a 2D image of the objects having the projected coded light pattern projected thereupon to enable an image processing unit to extract reflected feature types according to the unique bi-dimensional formations, and to determine locations of the reflected feature types on respective epipolar lines in the 2D image. It is noted that the buffering electric circuit may be implemented in all the claimed variations of the apparatus of application Ser. No. 11/837,553 by supplying power to a driver of the projector or otherwise.

For example, any of the apparatuses disclosed in U.S. patent application Ser. No. 12/515,715 entitled “3D GEOMETRIC MODELING AND 3D VIDEO CONTENT CREATION” (which is incorporated herein in its entirety by reference) may utilize the disclosed electric circuit in the following way: An apparatus configured to obtain data from a 2D (two-dimensional) image in order to determine the 3D (three-dimensional) shape of objects appearing in said 2D image, said apparatus including: (1) a first bi-dimensional coded light pattern having a plurality of feature types, each feature type being distinguishable according to a unique bi-dimensional formation and each feature type including a plurality of elements having varying light intensity, wherein said plurality of elements includes: (a) at least one maximum element; (b) at least one minimum element; and (c) at least one saddle element; (2) a second bi dimensional light pattern which is the same as said first bi-dimensional coded pattern with the one or more maximum and/or minimum elements inverted to minimum or maximum and in which the at least one saddle element remains unchanged, respectively; (3) a projection module configured to project said first bi-dimensional coded light pattern and said second bi-dimensional light pattern on said objects; (4) the buffering electric circuit discussed with respect to FIF. 1, wherein the buffering electric circuit is electrically connected to the projection module providing power to the projection module; (5) at least one imaging module configured to capture a first 2D image of said objects, having said first projected coded light pattern projected thereupon, said first 2D image including reflected said feature types, and said at least one imaging module is configured to capture a second 2D image of said objects, having said second coded light pattern projected thereupon, said second 2D image including reflected said feature types; and (6) an image processing module configured to: (i) obtain a resultant image from the subtraction of said second 2D image from said first 2D image, said resultant image including maximum, minimum and saddle points resulting from the subtraction; and (ii) extract from said resultant image, feature types' elements locations in said first and/or second image, based on the maximum, saddle and/or minimum elements locations in said resultant image.

It is noted that the buffering electric circuit may be implemented in all the claimed variations of the apparatus of application Ser. No. 12/515,715 by supplying power to a driver of the projection module or otherwise.

FIG. 8 is a block circuit diagram illustrating a circuit 800 for dithering of pulses provided to a projector. A power supply 810 has a switching frequency that is varied over time to reduce radiation peaks at any given frequency. A laser driver 820 is coupled to the power supply 810 to receive power from the power supply and provide current pulses to a laser 830. Timing between the current pulses is varied to spread electromagnetic interference noise over a range of frequencies such that the amplitude at spectral peaks decreases. In one embodiment, the timing between current pulses is varied randomly about a base timing. The timing may be varied within two percent of the base timing in one embodiment. In a further embodiment, each pulse has a rise time of at most 100 microseconds.

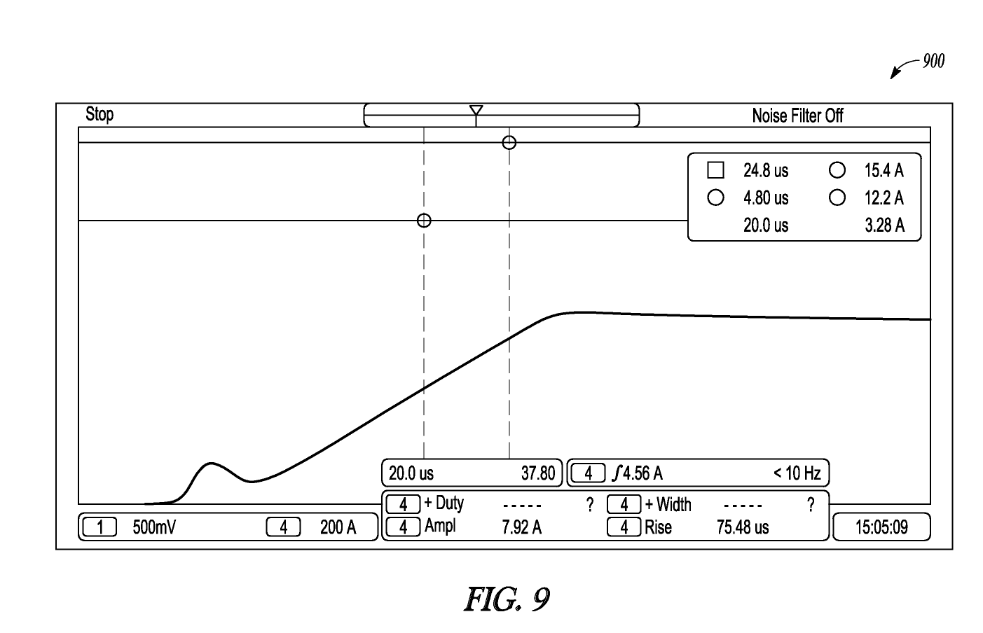

FIG. 9 is a graph 900 illustrating laser driver pulse shaping control of electromagnetic interference reduction. The rise time of the pulse is approximately 100 usec in one embodiment, with a diode breakthrough portion of the rise illustrated during the beginning of the rise. Note how the pulse dips following a quick rise, indicative of the breakthrough. The pulse continues to rise linearly, or almost linearly to a steady state for the remainder of the pulse.

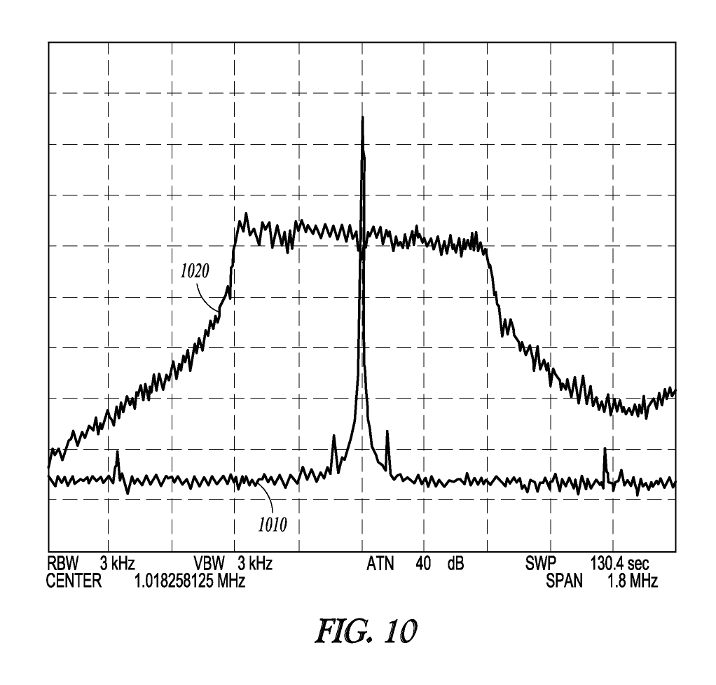

FIG. 10 is a graph illustrating a spectral analysis 1000 of both laser driver EMI spectrum without dithering at 1010 and with dithering at 1020. Note that without dithering 1010, there is a very high emission peak toward the middle of the curve, while with dithering, the emission is spread over a wider range of frequencies and having peaks significantly lower than that of the spectrum without dithering.

In further embodiments the circuit changes the power supply frequency over time, utilizing a method referred to as a spread spectrum method or dithering. The amplitude of spectral peak decreases as long as the frequency changes rapidly. Pulse shaping of the laser driver may be utilized to reduce EMI. In various embodiments, the power supply, driver current, or both may be dithered to reduce EMI.

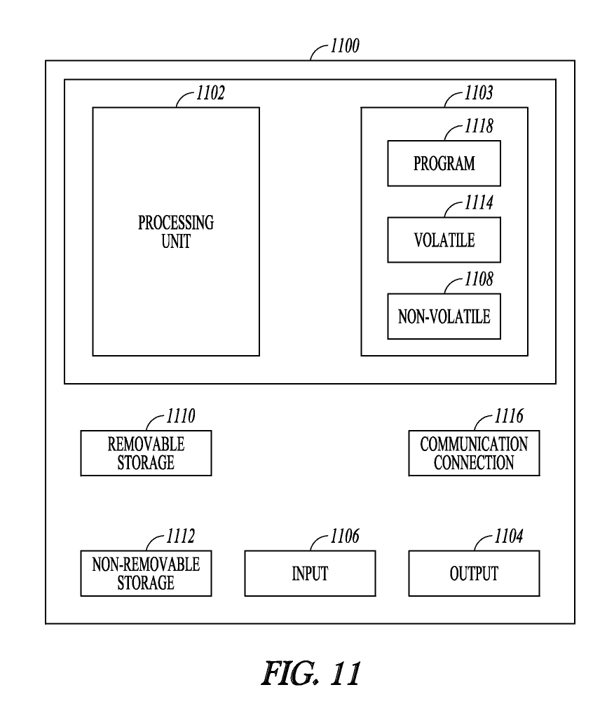

FIG. 11 is a block schematic diagram of a computer system 1100 to implement a controller according to an example embodiment. Fewer components than those shown may be used to implement the controller in various embodiments. One example computing device in the form of a computer 1100, may include a processing unit 1102, memory 1103, removable storage 1110, and non-removable storage 1112. Memory 1103 may include volatile memory 1114 and non-volatile memory 1108. Computer 1100 may include—or have access to a computing environment that includes—a variety of computer-readable media, such as volatile memory 1114 and non-volatile memory 1108, removable storage 1110 and non-removable storage 1112. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 1100 may include or have access to a computing environment that includes input 1106, output 1104, and a communication connection 1116. The computer may operate in a networked environment using a communication connection to connect to one or more remote computers, such as database servers. The remote computer may include a personal computer (PC), server, router, network PC, a peer device or other common network node, or the like. The communication connection may include a Local Area Network (LAN), a Wide Area Network (WAN) or other networks.

Computer-readable instructions stored on a computer-readable medium, such as a non-transitory medium, are executable by the processing unit 1102 of the computer 1100. A hard drive, CD-ROM, and RAM are some examples of articles including a non-transitory computer-readable medium. For example, a computer program 1118 capable of providing a generic technique to perform access control check for data access and/or for doing an operation on one of the servers in a component object model (COM) based system may be included on a CD-ROM and loaded from the CD-ROM to a hard drive. The computer-readable instructions allow computer 1100 to provide generic access controls in a COM based computer network system having multiple users and servers.

Following is a list of numbered embodiment examples which demonstrate several of the possible implementations of the above disclosed subject matter. It will be clear to a person who is of skill in the art that the invention is not limited to these numbered embodiments, which are offered by way of example only. The numbered embodiments include:

1. A buffering electric circuit, the circuit including:

a controllable current source, configured to obtain power from a power source and to provide energy to an energy storage module based on a current command issued by a controller;

the energy storage module, connected to a load;

a controller, configured to obtain:

(a) Information indicative of amount of energy stored in the energy storage module;

(b) Information indicative of amount of energy consumed by the load in a last pulse; and

(c) Information indicative of time between the last pulse and a consecutive pulse; wherein the controller is further configured to compute the current command based on (a), (b) and (c).

2. The electric circuit according to numbered embodiment 1, wherein the buffering electric circuit is configured to isolate the power source from the load, which is a high-power varying load.

3. The electric circuit according to any of numbered embodiments 1-2, wherein the buffering electric circuit is configured to prevent reflection of the load current onto the input source.

4. The electric circuit according to any of numbered embodiments 1-4, wherein the buffering electric circuit is configured to enable the use of load pulses in mobile system.

5. The electric circuit according to numbered embodiment 4, wherein the power source is selected from a group consisting of a battery, USB port and direct current (DC) Power supply.

6. The electric circuit according to any of numbered embodiments 1-5, wherein the buffering electric circuit enables powering of the load by a limited power source whose momentary output power is smaller than a momentary requirement of the load during operation of the load.

7. The electric circuit according to any of numbered embodiments 1-6, wherein the energy storage module is a capacitor.

8. The electric circuit according to any of numbered embodiments 1-7, wherein the energy storage module is an inductor.

9. The electric circuit according to any of numbered embodiments 1-8, wherein the controller is configured to obtain (a) by obtaining (x) and (y) and computing a value of (a) for a later pulse.

10. The electric circuit according to any of numbered embodiments 1-9, wherein an energy storage size of the energy storage module is constant, wherein the controller is configured to estimate parameter (a) based on the energy storage size and on a plurality of parameters pertaining to power induced into the energy storage module.

11. The electric circuit according to any of numbered embodiments 1-10, wherein the controller is configured to obtain parameter (b) by measuring a plurality of load parameters out of the parameters: pulse width, voltage and current.

12. The electric circuit according to any of numbered embodiments 1-11, wherein information indicative of relationships between load forwarded voltages and respective currents in the electric buffering circuits is provided to the controller, wherein the controller is configured to estimate parameter (b) based on the provided information and on information indicative of current of the load.

13. The electric circuit according to any of numbered embodiments 1-12, wherein the controller is configured to estimate parameter (b) by known load parameters: pulse width, voltage and current.

14. The electric circuit according to any of numbered embodiments 1-13, wherein the controller is configured to obtain parameter (c) by measuring a plurality of load parameters out of the parameters: pulse width, voltage and current.

15. The electric circuit according to any of numbered embodiments 1-14, wherein the controller is configured to estimate parameter (c) by known load parameters: pulse width and delay.

16. The electric circuit according to any of numbered embodiments 1-15, wherein the controller uses the value of energy consumed by an auxiliary circuit which includes the load and the energy storage module for determining the current commands.

17. The electric circuit according to numbered embodiment 16, wherein the controller is configured to estimate auxiliary energy by known electric design parameters.

18. The electric circuit according to any of numbered embodiments 16-17, wherein the controller is configured to estimate auxiliary energy to be negligible for certain designs.

19. The electric circuit according to any of numbered embodiments 16-18, wherein the controller is configured to estimate auxiliary energy to include the consumption by the load.

20. The electric circuit according to numbered embodiment 1-19, wherein the energy storage module is operable to store energy of at least one pulse of the load.

21. The electric circuits according to numbered embodiment 1-20, wherein the controller includes control loop designed to cope with output load power which varies with time.

22. The electric circuit according to any one of numbered embodiments 1, 20, and 21 wherein the controller is configured to compute (b) by calculating the average energy of several load pulses.

23. The electric circuit according to numbered embodiment 22, wherein the controller is operable to reduce a level of current drawn from the power source 5 by calculating the average energy of several load pulses.

24. The electric circuit according to numbered embodiment 1-23, operable to operate under at least two types of control loops by operating under a first control loop during the load pulse and operating under a second control loop between pulses.

25. The electric circuit according to numbered embodiment 1-24, wherein the controller is configured to obtain the Information indicative of time between the last pulse and a consecutive pulse by obtaining information indicative of the time between pulses.

26. An apparatus configured to obtain distance data from a 2D (two-dimensional) image of a scene including one or more objects, said apparatus including:

a bi-dimensional coded light pattern including multiple appearances of a finite set of feature types, each feature type being distinguishable according to a unique bidimensional formation;

a projector configured to project the coded light pattern on the objects, such that a distance between adjacent epipolar lines associated with substantially identical appearances of any given feature type is minimized according to a limiting epipolar separation factor, giving rise to a plurality of distinguishable epipolar lines separated by approximately a minimum safe distance for epipolar line distinction; and

the buffering electric circuit according to numbered embodiment 1, wherein the buffering electric circuit is electrically connected to the projector for providing power to the projector;

wherein the projector enables an imaging unit to capture a 2D image of the

objects having the projected coded light pattern projected thereupon to enable an image processing unit to extract reflected feature types according to the unique bidimensional formations, and to determine locations of the reflected feature types on respective epipolar lines in the 2D image.

27. An apparatus configured to obtain data from a 2D (two-dimensional) image in order to determine the 3D (three-dimensional) shape of objects appearing 5 in said 2D image, said apparatus including:

a first bi-dimensional coded light pattern having a plurality of feature types, each feature type being distinguishable according to a unique bi-dimensional formation and each feature type including a plurality of elements having varying light intensity, wherein said plurality of elements includes:

a) at least one maximum element;

b) at least one minimum element; and

c) at least one saddle element;

a second bi dimensional light pattern which is the same as said first bi-dimensional coded pattern with the one or more maximum and/or minimum elements inverted to minimum or maximum and in which the at least one saddle element remains unchanged, respectively;

a projection module configured to project said first bi-dimensional coded light pattern and said second bi-dimensional light pattern on said objects;

the buffering electric circuit according to numbered embodiment 1, wherein the buffering electric circuit is electrically connected to the projection module providing power to the projection module;

at least one imaging module configured to capture a first 2D image of said objects, having said first projected coded light pattern projected thereupon, said first 2D image including reflected said feature types, and said at least one imaging module is configured to capture a second 2D image of said objects, having said second coded light pattern projected thereupon, said second 2D image including reflected said feature types; and

an image processing module configured to:

i) obtain a resultant image from the subtraction of said second 2D image from said first 2D image, said resultant image including maximum, minimum and saddle points resulting from the subtraction; and

ii) extract from said resultant image, feature types' 5 elements locations in said first and/or second image, based on the maximum, saddle and/or minimum elements locations in said resultant image.

28. A method for buffering, the method including:

obtaining: (a) Information indicative of amount of energy stored in an energy storage module; (b) Information indicative of amount of energy consumed by a load which is connected to the energy storage module in a last pulse of the load; and (c)

information indicative of time between the last pulse and a consecutive pulse of the load;

computing a current command based on (a), (b) and (c);

obtaining by a controllable current source power from a power source, wherein a magnitude of the obtained power is determined by the current command;

providing the obtained power to the energy storage module.

29. The method according to numbered embodiment 28, including isolating, by a buffering electric circuit which includes the energy storage module and the controllable current source, the power source from the load, which is a high-power varying load.

30. The method according to numbered embodiment 29, including preventing reflection of the load current onto the input source.

31. The method according to numbered embodiment 29, including enabling use of load pulses in a portable hand-held system.

32. The method according to any of numbered embodiments 28-31, wherein the power source is selected from a group consisting of a battery, USB port and direct current (DC) Power supply.

33. The method according to any of numbered embodiments 28-32, including powering of the load by a limited power source whose momentary output power is smaller than a momentary requirement of the load during operation thereof.

34. The method according to any of numbered embodiments 28-33, wherein the energy storage module 5 is a capacitor.

35. The method according to any of numbered embodiments 28-34, wherein the energy storage module is an inductor.

36. The method according to any of numbered embodiments 28-35, wherein the obtaining of the Information indicative of amount of energy stored in an energy storage module includes obtaining (x) and (y) and computing a value of (a) for a later pulse (al).

37. The method according to any of numbered embodiments 28-36, wherein an energy storage size of the energy storage module is constant, wherein the obtaining of (a) includes estimating parameter (a) based on the energy storage size and on a plurality of parameters pertaining to power induced into the energy storage module.

38. The method according to any of numbered embodiments 28-37, wherein the obtaining of parameter (b) includes measuring a plurality of load parameters out of the group of parameters consisting of: pulse width, voltage and current.

39. The method according to any of numbered embodiments 28-38, wherein the obtaining of parameter (b) includes estimating parameter (b) based on information indicative of current of the load and on information indicative of relationships between load forwarded voltages and respective currents in a buffering electric circuit which includes the energy storage module and the controllable current source.

40. The method according to any of numbered embodiments 28-39, wherein the obtaining of parameter (b) includes estimating parameter (b) by known load parameters: pulse width, voltage and current.

41. The method according to any of numbered embodiments 28-40, wherein the obtaining of parameter (c) includes measuring a plurality of load parameters out of the parameters selected from the group consisting of: pulse width, voltage and current.

42. The method according to any of numbered embodiments 28-41, wherein the obtaining of parameter (c) includes estimating parameter (c) by known load parameters: pulse 5 width and delay.

43. The method according to any of numbered embodiments 28-42, including using a value of energy consumed by an auxiliary circuit which includes the load and the energy storage module for determining the current commands.

44. The method according to numbered embodiment 43, including estimating auxiliary energy by known electric design parameters.

45. The method according to any of numbered embodiments 43-44, including estimating auxiliary energy to be negligible for certain designs.

46. The method according to any of numbered embodiments 43-45, including estimating auxiliary energy to include the consumption by the load.

47. The method according to any of numbered embodiments 43-46, including estimating auxiliary energy to include the consumption by the load.

48. The method according to any of numbered embodiments 28-47, wherein the energy storage module is operable to store energy of at least one pulse of the load.

49. The electric circuits according to any of numbered embodiments 28-48, wherein the determining of the control command is executed by a controller which includes a control loop designed to cope with output load power which varies with time.

50. The electric circuit according to any one numbered embodiments 28 through 51, wherein the obtaining of parameter (b) includes calculating the average energy of several load pulses.

51. The method according to numbered embodiment 28-50, including reducing a level of current drawn from the power source by calculating the average energy of several load pulses.

52. The method according to any of numbered embodiments 28-51, wherein the obtaining of the Information indicative of time between the last pulse and a consecutive pulse includes obtaining information indicative of the 5 time between pulses.

Driver—linear charge of capacitor examples:

53. A circuit comprising:

an energy storage device configured to provide pulses of energy to a load;

a charger circuit coupled to the energy storage device to receive electrical energy from a peak energy constrained supply;

a controller coupled to the charger circuit to control the charger circuit to charge the energy storage device as a function of time between pulses to reduce peak energy provided by the peak energy constrained supply.

54. The circuit of claim 53 wherein the controller controls the charger circuit to charge the energy storage device in a substantially linear manner between pulses provided by the energy storage device.

55. The circuit of any of claims 53-54 wherein the supply characteristics correspond to a chemical battery supply, a USB port, or a direct current power supply.

56. The circuit of any of claims 53-55 wherein the time between pulses corresponds to a frames per second setting of the load comprising a light projector.

57. The circuit of claim 56 wherein the frames per second of the projector is variable between five frames per second and 60 frames per second.

58. The circuit of any of claims 53-57 and further comprising a driver coupled to the energy storage device comprising a super capacitor to receive current from the super capacitor and provide pulses of current to the load.

59. The circuit of claim 58 wherein the controller is operable to place the circuit in a sleep mode to disable the driver while a pulse is being provided.

60. The circuit of any of claims 53-59 wherein the controller is operable to charge the load comprising a super capacitor with a current that is an average of current calculated to replenish energy used to provide a last pulse of energy.

61. The circuit of any of claims 53-60 wherein the controller is operable to charge the load comprising a super capacitor with a current that is an average of current calculated to charge the capacitor sufficiently to provide a next pulse of energy.

62. A circuit comprising:

a projector;

a super capacitor to provide pulses of energy to the projector;

a capacitor charger circuit coupled to the super capacitor and to receive electrical energy from a supply;

a controller coupled to the capacitor charger to control the capacitor charger to charge the super capacitor as a function of time between pulses and supply characteristics.

63. The circuit of claim 62 wherein the projector comprises a laser VCSEL.

64. The circuit of any of claims 62-63 and further comprising a supply coupled to the capacitor charger, wherein the supply comprises a battery having a voltage that varies as a function of current drawn from the battery.

65. The circuit of any of claims 62-64 wherein the controller controls the charger circuit to charge the energy storage device in a substantially linear manner between pulses provided by the energy storage device.

66. The circuit of any of claims 62-65 wherein the controller is operable to place the circuit in a sleep mode to disable the driver while a pulse is being provided.

67. A method comprising:

determining a time between pulses of energy; and

charging an energy storage device via a charging circuit and power supply during the time between pulses of energy as a function of the time between pulses of energy such that charging the energy storage device is performed in a substantially linear manner with sufficient charge to provide a next pulse of energy to a load.

68. The method of claim 67 and further comprising providing the next pulse of energy to the load and placing the charging circuit in a sleep mode while providing the next pulse of energy.

69. The method of any of claims 67-68 and further comprising modulating the charging of the energy storage device as a function of other loads on the power supply.

70. The method of any of claims 67-69 and further comprising determining a rate of charge of the energy storage device as a function of the amount of energy provided by the energy storage device for a last pulse and the time between the last pulse and a next pulse.

71. The method of any of claims 67-70 wherein the energy storage device comprises a super capacitor.

72. The method of any of claims 67-71 wherein the load comprises a light projector.

Varied timing of pulses examples:

73. A circuit comprising:

a power supply having a switching frequency that is varied over time; and

a laser driver coupled to the power supply to receive power from the power supply and provide current pulses to a laser, wherein timing between the current pulses is varied to spread electromagnetic interference noise over a range of frequencies.

74. The circuit of claim 73 wherein the timing is varied randomly about a base timing.

75. The circuit of any of claims 73-74 wherein the timing is varied within two percent of the base timing.

76. The circuit of any of claims 73-75 wherein each pulse has a rise time of at most 100 microseconds.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

It will also be understood that the system according to the presently disclosed subject matter can be implemented, at least partly, as a suitably programmed computer. Likewise, the presently disclosed subject matter contemplates a computer program being readable by a computer for executing the disclosed method. The presently disclosed subject matter further contemplates a machine-readable memory tangibly embodying a program of instructions executable by the machine for executing the disclosed method.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the scope of the appended claims.

It will be appreciated that the embodiments described above are cited by way of example, and various features thereof and combinations of these features can be varied and modified.

While various embodiments have been shown and described, it will be understood that there is no intent to limit the invention by such disclosure, but rather, it is intended to cover all modifications, combinations of elements and features, and alternate constructions falling within the scope of the invention, as defined in the appended claims.

What is claimed is:

1. A circuit comprising:
an energy storage device configured to provide pulses of energy to a load;
a charger circuit coupled to the energy storage device to receive electrical energy from a peak energy constrained supply;
a controller coupled to the charger circuit to control the charger circuit to charge the energy storage device as a function of time between pulses to reduce peak energy provided by the peak energy constrained supply.

2. The circuit of claim 1 wherein the controller controls the charger circuit to charge the energy storage device in a substantially linear manner between pulses provided by the energy storage device.

3. The circuit of claim 1 wherein the supply characteristics correspond to a chemical battery supply, a USB port, or a direct current power supply.

4. The circuit of claim 1 wherein the time between pulses corresponds to a frames per second setting of the load comprising a light projector.

5. The circuit of claim 4 wherein the frames per second of the projector is variable between five frames per second and 60 frames per second.

6. The circuit of claim 1 and further comprising a driver coupled to the energy storage device comprising a super capacitor to receive current from the super capacitor and provide pulses of current to the load.

7. The circuit of claim 6 wherein the controller is operable to place the circuit in a sleep mode to disable the driver while a pulse is being provided.

8. The circuit of claim 1 wherein the controller is operable to charge the load comprising a super capacitor with a current that is an average of current calculated to replenish energy used to provide a last pulse of energy.

9. The circuit of claim 1 wherein the controller is operable to charge the load comprising a super capacitor with a current that is an average of current calculated to charge the capacitor sufficiently to provide a next pulse of energy.

10. A circuit comprising:
a projector;
a super capacitor to provide pulses of energy to the projector;
a capacitor charger circuit coupled to the super capacitor and to receive electrical energy from a supply;
a controller coupled to the capacitor charger to control the capacitor charger to charge the super capacitor as a function of time between pulses and supply characteristics.

11. The circuit of claim 10 wherein the projector comprises a laser VCSEL.

12. The circuit of claim 10 and further comprising a supply coupled to the capacitor charger, wherein the supply comprises a battery having a voltage that varies as a function of current drawn from the battery.

13. The circuit of claim 10 wherein the controller controls the charger circuit to charge the energy storage device in a substantially linear manner between pulses provided by the energy storage device.

14. The circuit of claim 10 wherein the controller is operable to place the circuit in a sleep mode to disable the driver while a pulse is being provided.

15. A method comprising:
determining a time between pulses of energy; and
charging an energy storage device via a charging circuit and power supply during the time between pulses of energy as a function of the time between pulses of energy such that charging the energy storage device is performed in a substantially linear manner with sufficient charge to provide a next pulse of energy to a load.

16. The method of claim 15 and further comprising providing the next pulse of energy to the load and placing the charging circuit in a sleep mode while providing the next pulse of energy.

17. The method of claim 15 and further comprising modulating the charging of the energy storage device as a function of other loads on the power supply.

18. The method of claim 15 and further comprising determining a rate of charge of the energy storage device as a function of the amount of energy provided by the energy storage device for a last pulse and the time between the last pulse and a next pulse.

19. The method of claim 15 wherein the energy storage device comprises a super capacitor.

20. The method of claim 15 wherein the load comprises a light projector.

21. A circuit comprising:
a power supply having a switching frequency that is varied over time; and
a laser driver coupled to the power supply to receive power from the power supply and provide current pulses to a laser, wherein timing between the current pulses is varied to spread electromagnetic interference noise over a range of frequencies.

22. The circuit of claim 21 wherein the timing is varied randomly about a base timing.

23. The circuit of claim 21 wherein the timing is varied within two percent of the base timing.

24. The circuit of claim 21 wherein each pulse has a rise time of at most 100 microseconds.
